(19) United States
(12) Patent Application Publication
(10) Pub. No.: US 2023/0369483 A1
(43) Pub. Date: Nov. 16, 2023

(54) SEMICONDUCTOR DEVICE AND MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Mariko HANASATO, Nisshin-shi (JP); Masato NOBORIO, Nisshin-shi (JP); Yohei IWAHASHI, Nisshin-shi (JP)

(21) Appl. No.: 18/183,216

(22) Filed: Mar. 14, 2023

(30) Foreign Application Priority Data
May 13, 2022 (JP) 2022-079565

(51) Int. Cl. H01L 29/78; H01L 29/16; H01L 29/06; H01L 21/04; H01L 29/66

(52) U.S. Cl. CPC H01L 29/7811; H01L 29/1608; H01L 29/0623; H01L 29/7813; H01L 21/0465; H01L 29/66068

(57) ABSTRACT

A semiconductor device includes multiple connecting regions having a second conductivity type and disposed in a cell section and a boundary section. The connecting regions are located between bottom regions and a body region in a thickness direction of a semiconductor layer, in contact with the bottom regions and the body region, and repeatedly arranged at intervals at least in one direction so that a drift region is disposed between the connecting regions.

### CROSS REFERENCE TO RELATED APPLICATION

The present application claims the benefit of priority from Japanese Patent Application No. 2022-079565 filed on May 13, 2022. The entire disclosure of the above application is incorporated herein by reference.

### TECHNICAL FIELD

The present disclosure relates to a semiconductor device and a manufacturing method of a semiconductor device.

### BACKGROUND

There has been known a semiconductor device having a trench gate. The semiconductor device has a semiconductor layer divided into a cell section, an outer peripheral section, and a boundary section. The cell section has the trench gate. The outer peripheral section has a closed loop shape surrounding the cell section, and has a high breakdown-voltage structure such as a guard ring. The boundary section is disposed between the cell section and the outer peripheral section, and has a closed loop shape surrounding the cell section.

### SUMMARY

The present disclosure provides a semiconductor device that includes multiple connecting regions having a second conductivity type and disposed in a cell section and a boundary section. The connecting regions are located between multiple bottom regions and a body region in a thickness direction of a semiconductor layer, in contact with the bottom regions and the body region, and repeatedly arranged at intervals at least in one direction so that a drift region is disposed between the connecting regions. The present disclosure also provides a manufacturing method of the semiconductor device.

### BRIEF DESCRIPTION OF DRAWINGS

Objects, features and advantages of the present disclosure will become apparent from the following detailed description made with reference to the accompanying drawings. In the drawings:

FIG. 1 is a diagram illustrating the positional relationship among a cell section, a boundary section, and an outer peripheral section divided in a semiconductor layer when the semiconductor layer is viewed from above;

FIG. 2 is a diagram illustrating a cross-sectional view of a part of a semiconductor device of a first embodiment taken along line II-II in FIG. 1;

FIG. 3 is a diagram illustrating a perspective view of the cell section in the semiconductor layer;

FIG. 4 is a diagram illustrating layouts of guard ring regions, boundary-section bottom regions, cell-section bottom regions, and connecting regions of the semiconductor device of the first embodiment;

FIG. 5 is a diagram illustrating a flow of a manufacturing method of the semiconductor device;

FIG. 6 is a diagram illustrating a cross-sectional view of a part of a semiconductor device of a comparative example in a process of manufacturing the semiconductor device;

FIG. 7 is a diagram illustrating a cross-sectional view of the part of the semiconductor device of the comparative example in a process of manufacturing the semiconductor device subsequent to the process illustrated in FIG. 6;

FIG. 8 is a diagram illustrating a cross-sectional view of the part of the semiconductor device of the comparative example in a process of manufacturing the semiconductor device subsequent to the process illustrated in FIG. 7;

FIG. 9 is a diagram illustrating a cross-sectional view of a part of a semiconductor device of a second embodiment taken along a line corresponding to line II-II in FIG. 1;

FIG. 10 is a diagram illustrating layouts of guard ring regions, boundary-section bottom regions, cell-section bottom regions, and connecting regions of the semiconductor device of the second embodiment; and

FIG. 11 is a diagram illustrating layouts of guard ring regions, boundary-section bottom regions, cell-section bottom regions, and connecting regions of a semiconductor device of a third embodiment.

### DETAILED DESCRIPTION

A semiconductor device may have a super junction structure (hereinafter, referred to as an SJ structure) in a cell section and a boundary section of a semiconductor layer. The SJ structure is a structure in which an n-type region and a p-type region are alternately repeated at least in one direction. The semiconductor device with the SJ structure can have both a high breakdown voltage and a low on-resistance.

The semiconductor device may further have a trench gate, and the SJ structure may be disposed at a position deeper than the trench gate. In such a case, a p-type connecting region is required to connect the p-type region forming the SJ structure and a p-type body region disposed in a surface layer portion of the semiconductor layer.

A semiconductor device according to an aspect of the present disclosure includes a semiconductor layer and a trench gate disposed on a main surface of the semiconductor layer. The semiconductor layer is divided into a cell section, an outer peripheral section, and a boundary section. The outer peripheral section has a closed loop shape surrounding the cell section. The boundary section is disposed between the cell section and the boundary section, and has a closed loop shape surrounding the cell section. The semiconductor layer includes a drift region, a body region, a source region, multiple bottom regions, and multiple connecting regions. The drift region has a first conductivity type and is disposed in the cell section, the boundary section, and the outer peripheral section. The body region has a second conductivity type and is disposed on the drift region at least in the cell section and the boundary section. The source region has the first conductivity type and is disposed on the body region in the cell section. The bottom regions have the second conductivity type. The bottom regions are disposed in the cell section and the boundary section, located at positions deeper than the trench gate, and repeatedly arranged at intervals at least in one direction so that the drift region is disposed between the bottom regions. The connecting regions have the second conductivity type. The connecting regions are disposed in the cell section and the boundary section, located between the bottom regions and the body region in a thickness direction of the semiconductor layer, in contact with the bottom regions and the body region, and repeatedly arranged at intervals at least in one direction so that the drift region is disposed between the connecting regions. The trench gate is disposed in the cell section, and extends from the main surface of the semiconductor layer into the drift region disposed between the connecting regions through the source region and the body region.

In the semiconductor device described above, the connecting regions repeatedly arranged at intervals are formed also in the boundary section in the semiconductor layer in a manner similar in the cell section of the semiconductor layer. Therefore, the connecting regions disposed in the cell section and the connecting regions disposed in the boundary section in the semiconductor layer can have a substantially uniform shape. As a result, an occurrence of unintended electric field concentration in the boundary section in the semiconductor layer can be restricted, and a decrease in breakdown voltage can be restricted.

A manufacturing method according to another aspect of the present disclosure is a manufacturing method of a semiconductor device that includes a semiconductor layer and a trench gate disposed on a main surface of the semiconductor layer. The semiconductor layer is divided into a cell section, an outer peripheral section, and a boundary section. The outer peripheral section has a closed loop shape surrounding the cell section. The boundary section is disposed between the cell section and the boundary section, and has a closed loop shape surrounding the cell section. The manufacturing method includes forming multiple bottom regions of a second conductivity type on an upper surface of a lower drift region of a first conductivity type, forming an upper drift region of the first conductivity type on the lower drift region and the bottom regions, patterning a mask on the upper drift region and introducing a second conductivity type impurity into an upper surface of the upper drift region through the mask to form multiple connecting regions, forming a body region of the second conductivity type on the upper drift region and the connecting regions, and forming a source region of the first conductivity type on the body region. The lower drift region is formed in the cell section, the boundary section, and the outer peripheral section. The bottom regions are formed at least in the cell section and the boundary section, located at positions deeper than the trench gate, and repeatedly arranged at intervals at least in one direction so that the lower drift region is disposed between the bottom regions. The upper drift region is formed at least in the cell section and the boundary section. The connecting regions are formed at least in the cell section and the boundary section, and repeatedly arranged at intervals at least in one direction so that the upper drift region is disposed between the connecting regions. The trench gate is formed in the cell section, and extends from the main surface of the semiconductor layer into the upper drift region disposed between the connecting regions through the source region and the body region.

In the manufacturing method described above, the connecting regions repeatedly arranged at intervals is formed also in the boundary section in the semiconductor layer in a manner similar in the cell section in the semiconductor layer. Therefore, when forming the connecting regions in each of the cell section and the boundary section in the semiconductor layer, an occurrence of a difference in depth of upper surfaces of the cell section and the boundary section due to the difference in size of opening portions of the mask can be restricted. Therefore, the connecting regions disposed in the cell section and the connecting regions disposed in the boundary section in the semiconductor layer can have a substantially uniform shape. As a result, an occurrence of unintended electric field concentration in the boundary section in the semiconductor layer can be restricted, and a decrease in breakdown voltage can be restricted.

Semiconductor devices and manufacturing method of the semiconductor devices according to the present disclosure will be described with reference to the accompanying drawings. In the drawings, only some of common components may be denoted by reference numerals for the purpose of clarity of illustration. In respective embodiments, common components are denoted by common reference numerals, and descriptions thereof will be omitted.

### First Embodiment

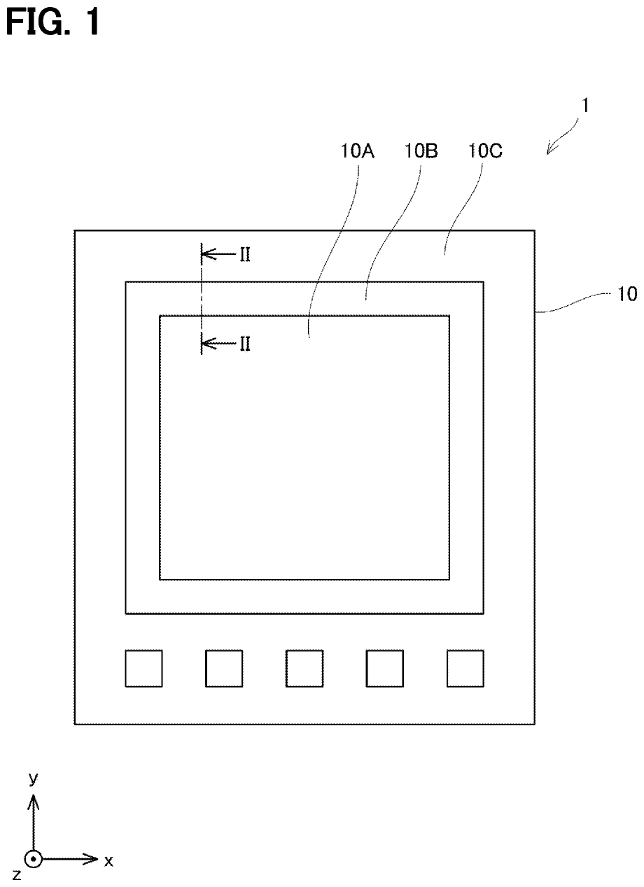

As illustrated in FIGS. 1 to 3, a semiconductor device 1 is a power device called a metal oxide semiconductor field effect transistor (MOSFET), and is formed using a semiconductor layer 10. The material of the semiconductor layer 10 is not particularly limited, but may be silicon carbide (SiC), for example. The semiconductor device 1 may also be a power device called an insulated gate bipolar transistor (IGBT).

As illustrated in FIG. 1, the semiconductor layer 10 is divided into a cell section 10A, a boundary section 10B, and an outer peripheral section 10C when viewed from above the semiconductor layer 10 (hereinafter, referred to as “in plan view of the semiconductor layer 10”). The cell section 10A is a region located at a center of the semiconductor layer 10, and is a region in which a switching structure is formed as described later. The boundary section 10B is a region disposed between the cell section 10A and the outer peripheral section 10C, and has a closed loop shape surrounding the cell section 10A. The outer peripheral section 10C is a region around the cell section 10A and the boundary section 10B, and has a closed loop shape surrounding the cell section 10A and the boundary section 10B. In the outer peripheral section 10C, a high breakdown-voltage structure is formed as will be described later.

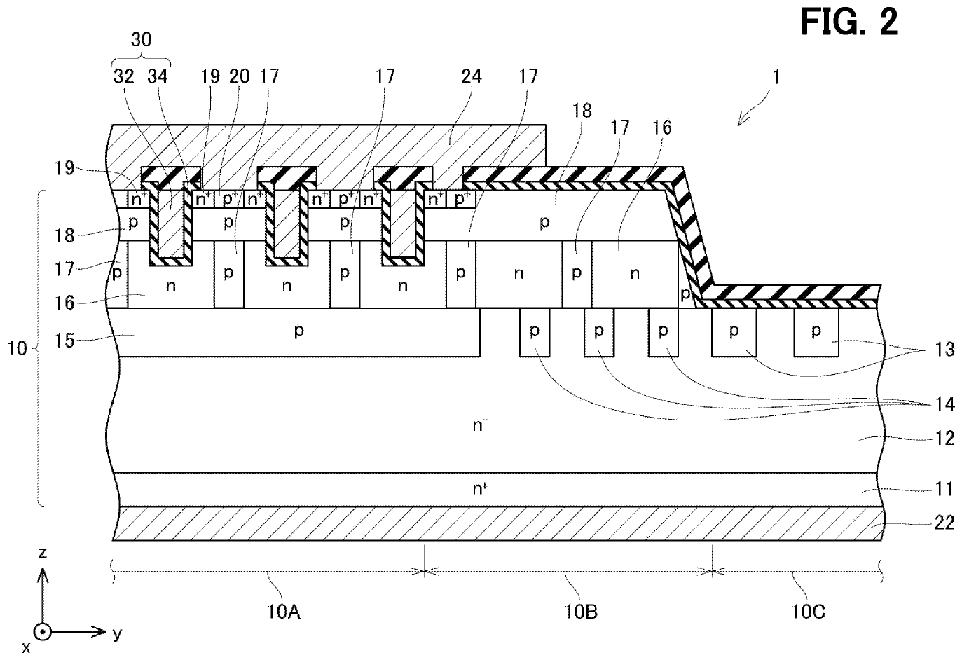

As illustrated in FIG. 2, the semiconductor device 1 includes the semiconductor layer 10, a drain electrode 22, a source electrode 24, and a plurality of trench gates 30. The semiconductor layer 10 includes a drain region 11, a lower drift region 12, a plurality of guard ring regions 13, a plurality of boundary-section bottom regions 14, a plurality of cell-section bottom regions 15, an upper drift region 16, a plurality of connecting regions 17, a body region 18, a plurality of source regions 19, and a plurality of contact regions 20. The cell section 10A is a region in which the trench gates 30 are disposed and a region through which current flows between the drain electrode 22 and the source electrode 24. The outer peripheral section 10C is a region in which the guard ring regions 13 are disposed, and is a region outside an innermost one of the guard ring regions 13. The boundary section 10B is a region between the cell section 10A and the outer peripheral section 10C, and extends from an outermost peripheral edge of the trench gates 30 provided in the cell section 10A to the innermost one of the guard ring regions 13 in the outer peripheral section 10C.

An upper surface of the semiconductor layer 10 is recessed in a range corresponding to the outer peripheral section 10C, and a step is formed between the boundary section 10B and the outer peripheral section 10C. In other words, the cell section 10A and the boundary section 10B in the semiconductor layer 10 are formed in a mesa shape and protrude upward as compared with the upper surface of the outer peripheral section 10C. The upper surface of the semiconductor layer 10 corresponds to a main surface of the semiconductor layer 10.

The drain electrode 22 covers a lower surface of the semiconductor layer 10. The drain electrode 22 is disposed over the cell section 10A, the boundary section 10B, and the outer peripheral section 10C, and is in contact with the entire lower surface of the semiconductor layer 10.

The source electrode 24 covers the upper surface of the semiconductor layer 10. The source electrode 24 is disposed over the cell section 10A and a part of the boundary section 10B, and is in contact with the upper surface of the semiconductor layer 10 exposed through opening portions of an interlayer insulating film formed on the upper surface of the semiconductor layer 10.

The drain region 11 is an n-type region including n-type impurities at high concentration. The drain region 11 is disposed at the lower surface of the semiconductor layer 10 over the cell section 10A, the boundary section 10B, and the outer peripheral section 10C. The drain region 11 is in ohmic contact with the drain electrode 22.

The lower drift region 12 is an n-type region having a lower n-type impurity concentration than the drain region 11. The lower drift region 12 is disposed over the cell section 10A, the boundary section 10B, and the outer peripheral section 10C. The lower drift region 12 is formed, for example by crystal growth from an upper surface of the drain region 11 using a crystal growth technique. The lower drift region 12 is called a drift region together with the upper drift region 16 which will be described later.

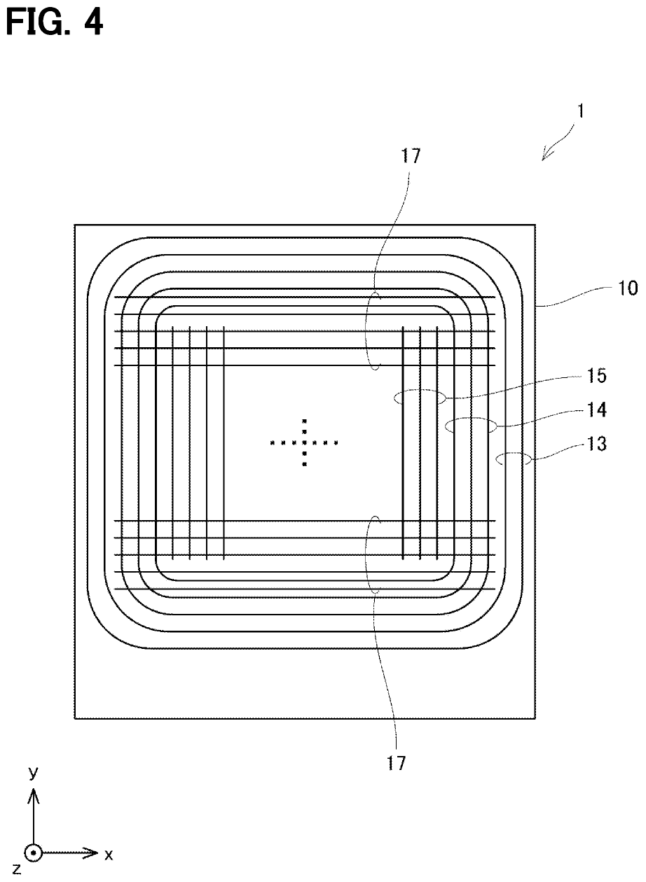

The guard ring regions 13 are p-type regions including p-type impurities. Each of the guard ring regions 13 is disposed in the outer peripheral section 10C, and has a closed loop shape surrounding the cell section 10A and the boundary section 10B along the outer peripheral section (see FIG. 4). The guard ring regions 13 are repeatedly arranged at intervals in a radial direction, that is, a direction connecting the center of the cell section 10A and the outer peripheral section 10C in plan view of the semiconductor layer 10. Between adjacent two of the guard ring regions 13, portions of the lower drift region 12 are disposed. The guard ring regions 13 are formed, for example, by introducing p-type impurities into portions of the upper surface of the lower drift region 12 using an ion implantation technique. The guard ring regions 13 are an example of the high breakdown-voltage structure. The potentials of the guard ring regions 13 are floating.

The boundary-section bottom regions 14 are p-type regions including p-type impurities. Each of the boundary-section bottom regions 14 is disposed in the boundary section 10B, and has a closed loop shape surrounding the cell section 10A along the boundary section 10B (see FIG. 4). The boundary-section bottom regions 14 are located at positions deeper than the trench gates 30. The boundary bottom regions 14 are repeatedly arranged at intervals in the radial direction in plan view of the semiconductor layer 10. Between adjacent two of the boundary-section bottom regions 14, portions of the lower drift region 12 are disposed. The boundary-section bottom regions 14 and the portions of the lower drift region 12 disposed between adjacent two of the boundary-section bottom regions 14 are adjusted in width and impurity concentration to achieve charge valance, and form an SJ structure. The portions of the lower drift region 12 disposed between adjacent two of the boundary-section bottom regions 14 may have a higher impurity concentration than other portions of the lower drift region 12. The boundary-section bottom regions 14 are formed, for example, by introducing p-type impurities into portions of the upper surface of the lower drift region 12 using the ion implantation technique. The boundary-section bottom regions 14 are called bottom regions together with the cell-section bottom regions 15.

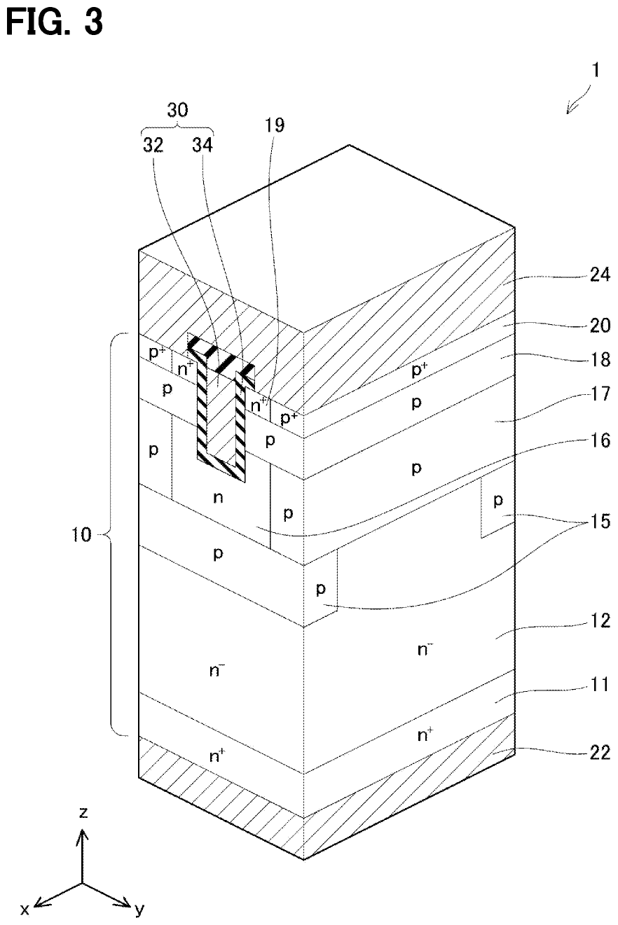

As illustrated in FIG. 2 and FIG. 3, the cell-section bottom regions 15 are p-type regions including p-type impurities. Each of the cell-section bottom regions 15 is disposed in the cell section 10A and is disposed at a position deeper the trench gates 30. In plan view of the semiconductor layer 10, the cell-section bottom regions 15 extend along at least one direction (y-direction in this example, and a direction orthogonal to the longitudinal direction of the trench gates 30), and the cell-section bottom regions 15 are repeatedly arranged at intervals in a direction orthogonal to the one direction (x-direction in this example, and a direction parallel to the longitudinal direction of the trench gates 30). Between adjacent two of the cell-section bottom regions 15, portions of the lower drift region 12 are disposed. The cell-section bottom regions 15 and the portions of the lower drift region 12 disposed between adjacent two of the cell-section bottom regions 15 are adjusted in width and impurity concentration to achieve charge valance, and form an SJ structure. The portions of the lower drift region 12 disposed between adjacent two of the cell-section bottom regions 15 may have a higher impurity concentration than other portions of the lower drift region 12. The cell-section bottom regions 15 are formed, for example, by introducing p-type impurities into portions of the upper surface of the lower drift region 12 using the ion implantation technique. In the present embodiment, the x-direction corresponds to a first direction, and the y-direction corresponds to a second direction.

The upper drift region 16 is an n-type region including n-type impurities. The upper drift region 16 is disposed over the cell section 10A and the boundary section 10B. The upper drift region 16 may have an n-type impurity concentration equal to or higher than the n-type impurity concentration of the lower drift region 12. The upper drift region 16 is in contact with bottom surfaces and lower portions of side surfaces of the trench gates 30. The upper drift region 16 is also in contact with the portions of the lower drift region 12 disposed between adjacent two of the cell-section bottom regions 15. The upper drift region 16 is formed, for example, by crystal growth from upper surfaces of the lower drift region 12 and the bottom regions 14 and 15 using the crystal growth technique.

The connecting regions 17 are p-type regions including p-type impurities. The connecting regions 17 are disposed over the cell section 10A and the boundary section 10B. In a thickness direction of the semiconductor layer 10 (z-direction in this example), the connecting regions 17 are disposed between the bottom regions 14, 15 and the body region 18. Each of the connecting regions 17 has a lower surface being in contact with the bottom regions 14, 15 and an upper surface being in contact with body region 18. Accordingly, the bottom regions 14, 15 are electrically connected to the body region 18 through the connecting regions 17. Each of the connecting regions 17 extends in a direction different from the longitudinal direction of the cell-section bottom regions 15 in plan view of the semiconductor layer 10. In plan view of the semiconductor layer 10, each of the connecting regions 17 extends along one direction orthogonal to the longitudinal direction of the cell-section bottom regions 15 (x-direction in this example, and the direction parallel to the longitudinal direction of the trench gates 30), and the connecting regions 17 are repeatedly arranged at intervals in the direction orthogonal to the one direction (y-direction in this example, and the direction orthogonal to the longitudinal direction of the trench gates 30). The upper drift region 16 is disposed between adjacent two of the connecting regions 17. The connecting regions 17 are formed, for example, by introducing p-type impurities into portions of the upper surface of the upper drift region 16 using the ion implantation technique.

As illustrated in FIG. 4, each of the connecting regions 17 extends along the x-direction in plan view of the semiconductor layer 10. Portions of the connecting regions 17 extends to the boundary section 10B over the cell section 10A. Portions of the connecting regions 17 intersect with each of the cell-section bottom regions 15 and the boundary-section bottom regions 14.

As illustrated in FIG. 2 and FIG. 3, the body region 18 is a p-type region including p-type impurities. The body region 18 is disposed on the upper drift region 16 and the connecting regions 17 over the cell section 10A and the boundary section 10B. The body region 18 is in contact with the side surfaces of the trench gates 30 and separates the upper drift region 16 and the source regions 19. The body region 18 is formed, for example, by crystal growth from the upper surface of the upper drift region 16 using the crystal growth technique.

The source regions 19 are n-type regions including n-type impurities at high concentration. The source regions 19 are disposed in the cell section 10A and are disposed at the upper surface of the semiconductor layer 10 on the body region 18. The source regions 19 are in contact with upper portions of the side surfaces of the trench gates 30, respectively. Each of the source regions 19 extends in parallel with the longitudinal direction of the trench gates 30 in plan view of the semiconductor layer 10. Each of the source regions 19 is exposed through an opening portion of the interlayer insulating film formed on the upper surface of the semiconductor layer 10 and is in ohmic contact with the source electrode 24. The source regions 19 are n-type layers formed on the upper surface of the body region 18, for example, using the crystal growth technique.

The contact regions 20 are p-type regions including p-type impurities at a higher concentration than the body region 18. The contact regions 20 are disposed in the cell section 10A and are disposed at the upper surface of the semiconductor layer 10 on the body region 18. Each of the contact regions 20 extends in parallel with the longitudinal direction of the trench gates 30 in plan view of the semiconductor layer 10. Each of the contact regions 20 is exposed through an opening portion of the interlayer insulating film formed on the upper surface of the semiconductor layer 10 and is in ohmic contact with the source electrode 24. The contact regions 20 are formed, for example, by introducing p-type impurities into the n-type layers for forming the source regions 19 using the ion implantation technique. The source regions 19 are formed as the remainder when forming the contact regions 20 in the n-type layer by the ion implantation.

The trench gates 30 are disposed in the cell section 10A. The trench gates 30 extend from the upper surface of the semiconductor layer 10 into the upper drift region 16 through the source regions 19 and the body region 18. The trench gates 30 extends along at least one direction (x-direction in this example) and are repeatedly arranged at intervals in a direction orthogonal to the one direction (y-direction in this example) in plan view of the semiconductor layer 10. Thus, the trench gates 30 are arranged in a stripe shape in plan view of the semiconductor layer 10. The arrangement of the trench gates 30 is not limited to the stripe shape and may be other layouts. Each of the trench gates 30 includes a gate electrode 32 and a gate insulating film 34. The gate electrode 32 is insulated from the upper drift region 16, the body region 18, and the source region 19 by the gate insulating film 34, and is insulated from the source electrode 24 by the interlayer insulating film.

Thus, in the cell section 10A, the switching structure is formed of the drain electrode 22, the drain region 11, the lower drift region 12, the cell-section bottom regions 15, the upper drift region 16, the connecting regions 17, the body region 18, the source regions 19, the contact regions 20, the source electrode 24, the trench gates 30, and the like.

Next, the operation of the semiconductor device 1 will be described. When a voltage equal to or higher than a gate threshold voltage is applied to the gate electrode 32 in a state where a voltage is applied between the drain electrode 22 and the source electrode 24 such that a potential of the drain electrode 22 is higher than a potential of the source electrode 24, a channel is formed at a portion of the body region 18 adjacent to the gate insulating film 34. Electrons supplied from the source region 19 flow into the upper drift region 16 through the channel. The electrons flowing into the upper drift region 16 flow into the drain region 11 through the lower drift region 12. As a result, conduction occurs between the drain electrode 22 and the source electrode 24, and the semiconductor device 1 is turned on. On the other hand, when a voltage lower than the gate threshold voltage is applied to the gate electrode 32, the channel disappears and the semiconductor device 1 is turned off. In this way, the semiconductor device 1 can function as a switching element for controlling a current flowing between the drain electrode 22 and the source electrode 24 in accordance with the voltage applied to the gate electrode 32.

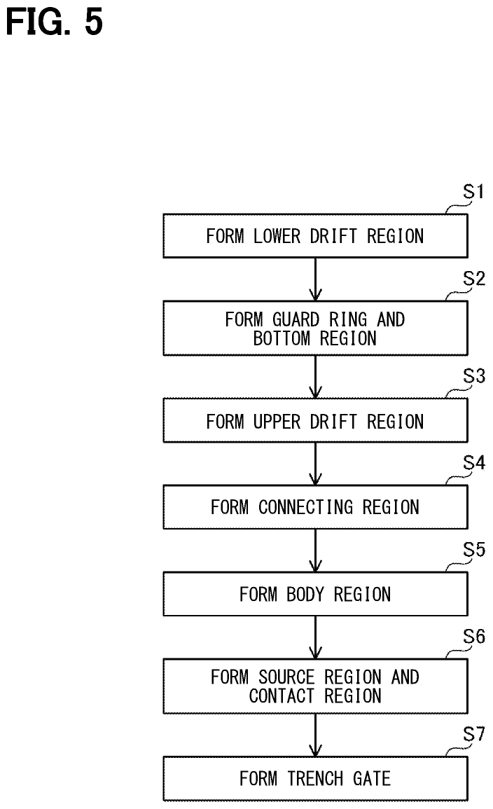

Next, with reference to FIG. 5, a part of processes of manufacturing the semiconductor device 1 will be described. Other processes can employ conventionally known processes.

First, at S1, an SiC substrate serving as the drain region 11 is prepared, and the lower drift region 12 is formed by crystal growth from the upper surface of the drain region 11 using the crystal growth technique.

Subsequently, at S2, after patterning a mask on the lower drift region 12, the guard ring regions 13, the boundary-section bottom regions 14 and the cell-section bottom regions 15 are formed by introducing the p-type impurities into portions of the upper surface of the lower drift region 12 through the mask using the ion implantation technique. After the ion implantation is executed, the mask is removed. A process of forming the guard ring regions 13, and a process of forming the boundary-section bottom regions 14 and the cell-section bottom regions 15 may be performed separately.

Subsequently, at S3, the upper drift region 16 is formed by crystal growth from the upper surface of the lower drift region 12 including the guard ring regions 13, the boundary-section bottom regions 14, and the cell-section bottom regions 15 using the crystal growth technique.

Subsequently, at S4, after patterning a mask on the upper drift region 16, the connecting regions 17 are formed by introducing the p-type impurities into portions of the upper surface of the upper drift region 16 through the mask using the ion implantation technique. After the ion implantation is executed, the mask is removed.

Subsequently, at S5, the body region 18 is formed by crystal growth from the upper surface of the upper drift region 16 including the connecting regions 17 using the crystal growth technique.

Subsequently, at S6, the n-type layer is formed by crystal growth from the upper surface of the body region 18 using the crystal growth technique. Then, the p-type impurities are introduced into portions of the n-type layer to form the contact region 20 using the ion implantation technique. The remainder when forming the contact regions 20 in the n-type layer by the ion implantation become the source regions 19.

Subsequently, at S7, the trench gates 30 are formed to reach the upper drift region 16 through the source regions 19 and the body region 18.

After that, the drain electrode 22, the source electrode 24, and the like are formed, and the semiconductor device 1 can be completed.

Next, the connecting regions 17 will be described. Among the connecting regions 17, the connecting regions 17 in the cell section 10A are repeatedly arranged at intervals in plan direction of the semiconductor layer 10 to ensure a current path, that is, to provide the upper drift region 16. On the other hand, since the boundary section 10B is not a region through which current flows, the connecting regions 17 in the boundary section 10B does not need to have such a shape. For example, it is conceivable to form a single connecting region 17 over an entire range of the boundary section 10B. However, the present inventors found that forming such a single connecting region 17 in the boundary section 10B cause the following issues.

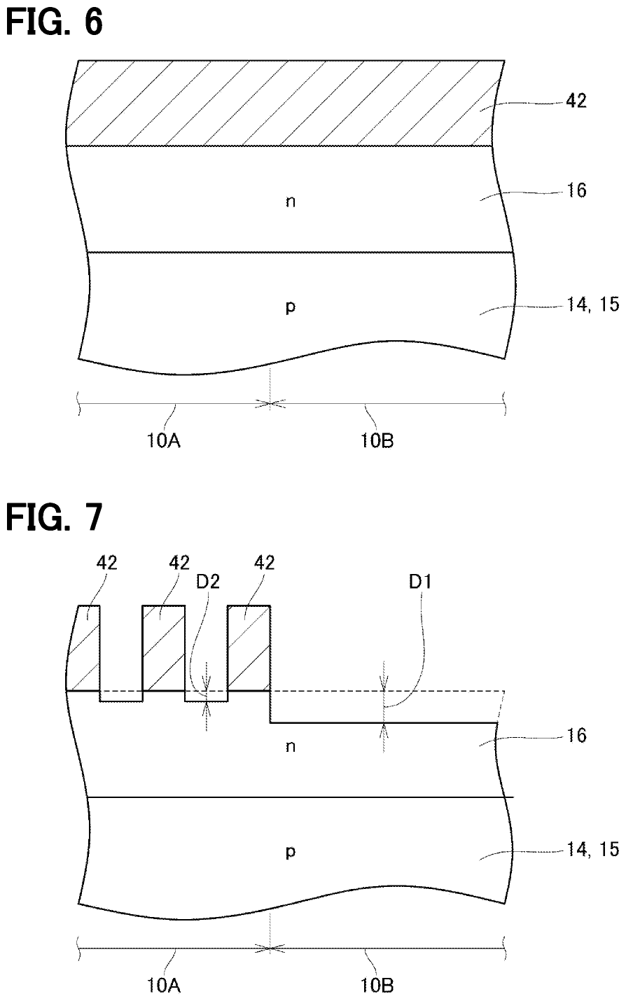

The issues of a comparative example in which a single connecting region 17 is formed in the boundary section 10B will be described with reference to FIGS. 6-8. FIGS. 6 to 8 are diagrams illustrating a cross-sectional view of a part of a semiconductor device of the comparative example including the cell section 10A and the boundary section 10B and explaining a process corresponding to the process at S4 in FIG. 5.

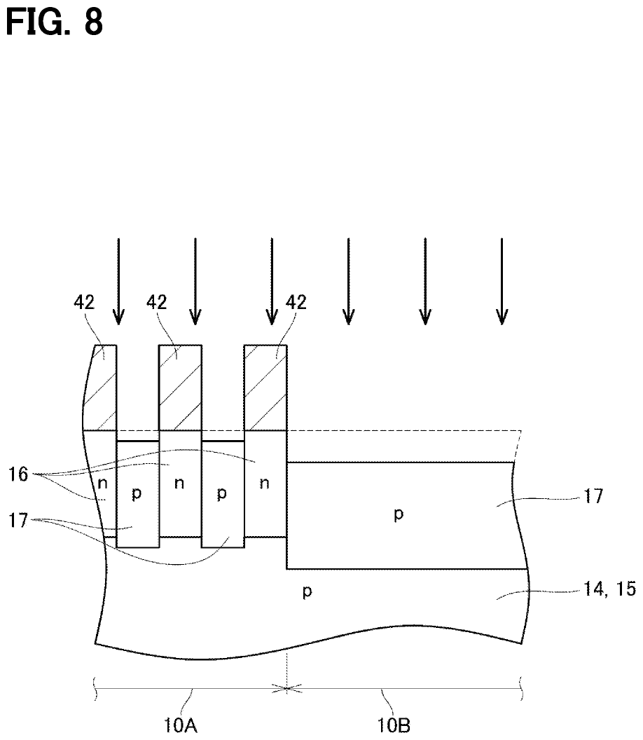

First, as illustrated in FIG. 6, a mask 42 is deposited on the upper drift region 16. Next, as illustrated in FIG. 7, the mask 42 is patterned. An opening portion formed in the mask 42 in the boundary section 10B is formed so as to correspond to the single connecting region 17, and is wider than opening portions formed in the mask 42 in the cell section 10A. Therefore, in etching for forming the opening portions in the mask 42, more etchant is supplied to the upper surface of the boundary section 10B than to the upper surface of the cell section 10A. Therefore, a depth D1 to which the upper surface of the boundary section 10B is etched is greater than a depth D2 to which the upper surface of the cell section 10A is etched, and the upper surface of the boundary section 10B is ground deeper than the upper surface of the cell section 10A. Subsequently, as illustrated in FIG. 8, the connecting regions 17 are formed by introducing the p-type impurities into portions of the upper drift region 16 using the ion implantation technique. At this time, since the upper surface of the boundary section 10B is ground deeper than the upper surface of the cell section 10A, the single connecting region 17 formed in the boundary section 10B is also formed at a position deeper than the connecting regions 17 formed in the cell section 10A. As described above, in the comparative example in which the single connecting region 17 is formed in the boundary section 10B, the depths of the connecting regions 17 in the cell section 10A and the boundary section 10B vary within a plane. Thus, there is concern that electric field concentration will occur especially in the boundary section 10B and the breakdown voltage will decrease.

On the other hand, in the semiconductor device 1 of the present embodiment, the connecting regions 17 are repeatedly arranged at intervals in the boundary section 10B as in the cell section 10A. Therefore, the connecting regions 17 arranged in each of the cell section 10A and the boundary section 10B can have a generally uniform shape. As a result, an occurrence of unintended electric field concentration in the boundary section 10B can be restricted, and a decrease in breakdown voltage can be restricted. Note that, in order to restrict the in-plane variation as in the comparative example, a width in a lateral direction (a width in the y-direction in FIG. 2) of the connecting regions 17 disposed in the boundary section 10B may be set to 10 times or less of a width in the lateral direction (a width in the y-direction in FIG. 2) of the connecting regions 17 disposed in the cell section 10A. The connecting regions 17 disposed in the boundary section 10B may also be called boundary-section connecting regions, and the connecting regions 17 disposed in the cell section 10A may also be called cell-section connecting regions.

### Second Embodiment

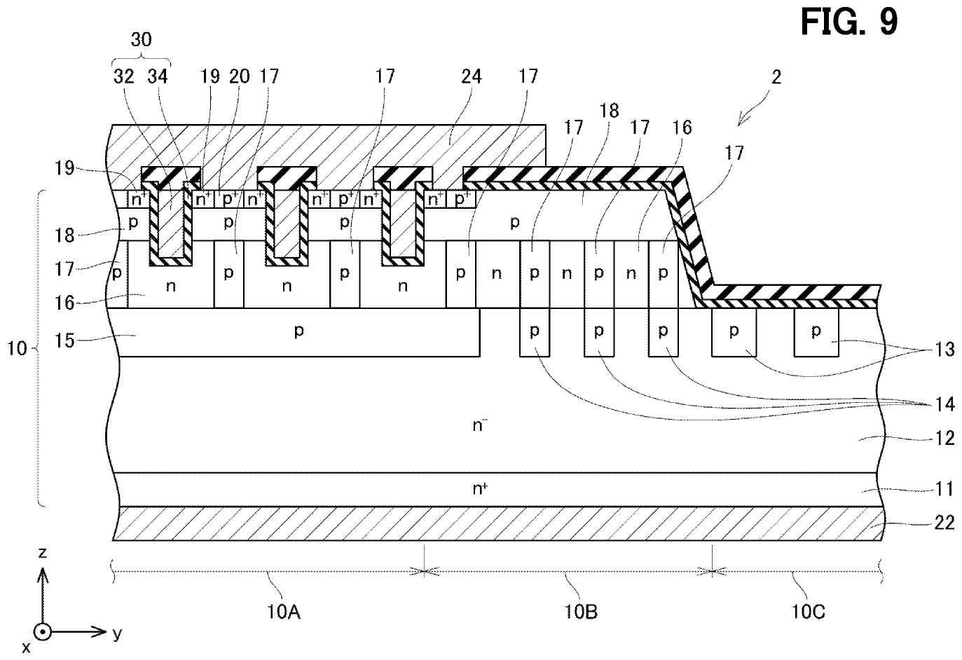

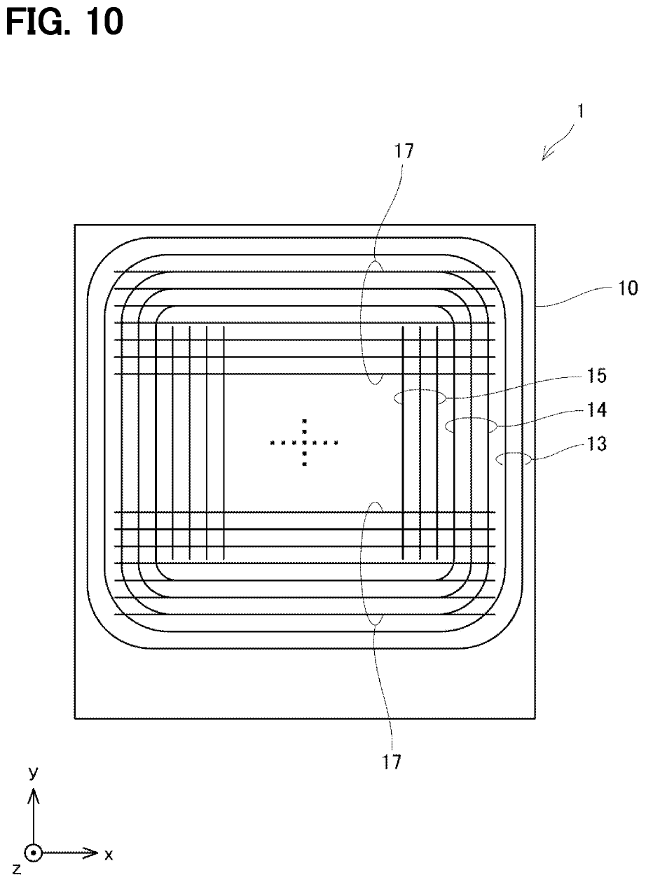

FIG. 9 and FIG. 10 illustrate a semiconductor device 2 according to a second embodiment. As in the semiconductor device 1 of the first embodiment, in the semiconductor device 2, each of the boundary-section bottom regions 14 extends in a closed loop shape surrounding the cell section 10A along the boundary section 10B. Therefore, each of the boundary-section bottom regions 14 has a portion extending along the x-direction and a portion extending along the y-direction in plan view of the semiconductor layer 10.

Each of the connecting regions 17 extends along the x-direction in plan view of the semiconductor layer 10. Thus, in portions where the boundary-section bottom regions 14 extend in the y-direction, the connecting regions 17 disposed in the boundary section 10B, that is, the boundary-section connecting regions extend in a direction orthogonal to the boundary-section bottom regions 14 disposed under the connecting regions 17, and intersect with each of the boundary-section bottom regions 14 in plan view of the semiconductor layer 10. Accordingly, the boundary-section bottom regions 14 and the connecting regions 17 can be in contact with each other at many portions. Furthermore, in portions where the boundary-section bottom regions 14 extend in the x-direction, the connecting regions 17 disposed in the boundary section 10B, that is, the boundary-section connecting regions extend in parallel and overlap with the corresponding boundary-section bottom regions 14 disposed under the connecting regions 17 in plan view of the semiconductor layer 10. Accordingly, the boundary-section bottom regions 14 and the connecting regions 17 can be in contact with each other at large area.

In the semiconductor device 2, the connecting regions 17 and the boundary-section bottom regions 14 can be in contact with each other at may portions and at large area in the boundary section 10B, so that the potential of the boundary-section bottom regions 14 can be stabilized.

### Third Embodiment

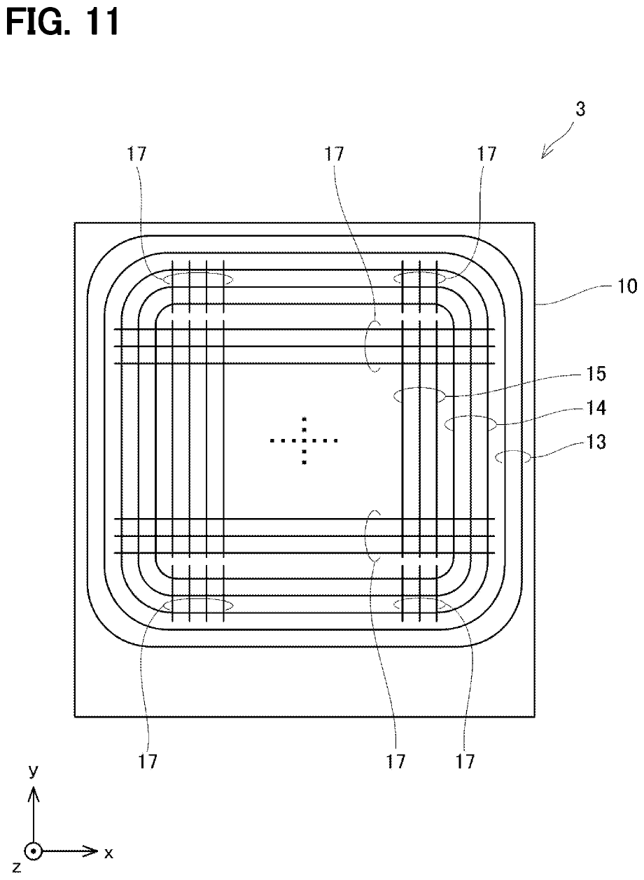

FIG. 11 illustrates a semiconductor device 3 according to a third embodiment. In the semiconductor device 3, in the portions where the boundary-section bottom regions 14 extend in the y-direction, the connecting regions 17 disposed in the boundary section 10B, that is, the boundary-section connecting regions extend in the direction orthogonal to the boundary-section bottom regions 14 disposed under the connecting regions 17, and intersect with each of the boundary-section bottom regions 14 in plan view of the semiconductor layer 10. Furthermore, also in the portions where the boundary-section bottom regions 14 extend in the x-direction, the connecting regions 17 disposed in the boundary section 10B, that is, the boundary-section connecting regions extend in a direction orthogonal to the boundary-section bottom regions 14 disposed under the connecting regions 17, and intersect with each of the boundary-section bottom regions 14 in plan view of the semiconductor layer 10. Alternatively, in the portions where the boundary-section bottom regions 14 extend in the x-direction, the connecting regions 17 disposed in the boundary section 10B may extend in a direction inclined with respect to each of the boundary-section bottom regions 14 disposed under the connecting regions 17 in plan view of the semiconductor layer 10.

Also in the semiconductor device 3, the connecting regions 17 and the boundary-section bottom regions 14 can be in contact with each other at may portions and at large area in the boundary section 10B, so that the potential of the boundary-section bottom regions 14 can be stabilized.

Although the embodiments have been described in detail above, these are merely examples and do not limit the scope of claims. The techniques described in the claims include various modifications and modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor layer divided into a cell section, an outer peripheral section, and a boundary section, the outer peripheral section having a closed loop shape surrounding the cell section, the boundary section disposed between the cell section and the boundary section and having a closed loop shape surrounding the cell section; and
a trench gate disposed on a main surface of the semiconductor layer, wherein the semiconductor layer includes
a drift region of a first conductivity type disposed in the cell section, the boundary section, and the outer peripheral section,
a body region of a second conductivity type disposed on the drift region at least in the cell section and the boundary section,
a source region of the first conductivity type disposed on the body region in the cell section,
a plurality of bottom regions of the second conductivity type disposed in the cell section and the boundary section, located at a plurality of positions deeper than the trench gate, and repeatedly arranged at an interval at least in one direction so that the drift region is disposed between the plurality of bottom regions, and
a plurality of connecting regions of the second conductivity type disposed in the cell section and the boundary section, located between the plurality of bottom regions and the body region in a thickness direction of the semiconductor layer, being in contact with the plurality of bottom regions and the body region, and repeatedly arranged at an interval at least in one direction so that the drift region is disposed between the plurality of connecting regions, and
wherein the trench gate is disposed in the cell section, and extends from the main surface of the semiconductor layer into the drift region disposed between the plurality of connecting regions through the source region and the body region.

2. The semiconductor device according to claim 1, wherein
the plurality of bottom regions includes a plurality of cell-section bottom regions disposed in the cell section and a plurality of boundary-section bottom regions disposed in the boundary section,
the plurality of cell-section bottom regions is repeatedly arranged at an interval in a first direction in plan view of the semiconductor layer,
the plurality of boundary-section bottom regions has a closed loop shape surrounding the cell section and is repeatedly arranged at an interval in a radial direction,
a plurality of connecting regions includes a plurality of cell-section connecting regions disposed in the cell section, and
in plan view of the semiconductor layer, the plurality of cell-section connecting regions is repeatedly arranged at an interval in a second direction different from the first direction.

3. The semiconductor device according to claim 2, wherein
the plurality of connecting regions includes a plurality of boundary-section connecting regions disposed in the boundary section, and
in plan view of the semiconductor layer, the plurality of boundary-section connecting regions extends in parallel and overlap with the plurality of boundary-section bottom regions disposed under the plurality of boundary-section connecting regions.

4. The semiconductor device according to claim 2, wherein
the plurality of connecting regions includes a plurality of boundary-section connecting regions disposed in the boundary section, and
in plan view of the semiconductor layer, the plurality of boundary-section connecting regions extends in a direction intersecting with each of the plurality of boundary-section bottom regions disposed under the plurality of boundary-section connecting regions.

5. The semiconductor device according to claim 4, wherein
in plan view of the semiconductor layer, the plurality of boundary-section connecting regions extends in a direction orthogonal to each of the plurality of boundary-section bottom regions disposed under the plurality of boundary-section connecting regions.

6. The semiconductor device according to claim 1, wherein
the plurality of connecting regions includes a plurality of boundary-section connecting regions disposed in the boundary section and a plurality of cell-section connecting regions disposed in the cell section, and
a width of the plurality of boundary-section connecting regions in a lateral direction is 10 times or less of a width of the plurality of cell-section connecting regions in a lateral direction.

7. The semiconductor device according to claim 1, wherein
the semiconductor layer is made of silicon carbide.

8. A manufacturing method of a semiconductor device including a semiconductor layer and a trench gate disposed on a main surface of the semiconductor layer, the semiconductor layer divided into a cell section, an outer peripheral section, and a boundary section, the outer peripheral section having a closed loop shape surrounding the cell section, the boundary section disposed between the cell section and the boundary section and having a closed loop shape surrounding the cell section, the manufacturing method comprising:
forming a plurality of bottom regions of a second conductivity type on an upper surface of a lower drift region of a first conductivity type;
forming an upper drift region of the first conductivity type on the lower drift region and the plurality of bottom regions;
patterning a mask on the upper drift region and introducing a second conductivity type impurity into an upper surface of the upper drift region through the mask to form a plurality of connecting regions;
forming a body region of the second conductivity type on the upper drift region and the plurality of connecting regions; and
forming a source region of the first conductivity type on the body region, wherein
the lower drift region is formed in the cell section, the boundary section, and the outer peripheral section,
the plurality of bottom regions is formed at least in the cell section and the boundary section, located at a plurality of positions deeper than the trench gate, and repeatedly arranged at an interval at least in one direction so that the lower drift region is disposed between the plurality of bottom regions,
the upper drift region is formed at least in the cell section and the boundary section,
the plurality of connecting regions is formed at least in the cell section and the boundary section, and repeatedly arranged at an interval at least in one direction so that the upper drift region is disposed between the plurality of connecting regions, and
the trench gate is formed in the cell section, and extends from the main surface of the semiconductor layer into the upper drift region disposed between the plurality of connecting regions through the source region and the body region.
